(19) United States
(12) Patent Application Publication
(10) Pub. No.: US 2006/0043407 A1
(43) Pub. Date: Mar. 2, 2006

(54) Semiconductor light emitting apparatus

(75) Inventor: Haruhiko Okazaki, Fukuoka-ken (JP)

Correspondence Address: BANNER & WITCOFF, LTD., ATTORNEYS FOR RESERVE;CLIENT NO. 4, 1001 G STREET, N.W., 11TH FLOOR, WASHINGTON, DC, 20001-4597, US

(73) Assignee: Kabushiki Kaisha Toshiba, Minato-ku (JP)

(21) Appl. No.: 11/212,100

(22) Filed: Aug. 26, 2005

(30) Foreign Application Priority Data
Aug. 26, 2004 (JP) 2004-246114
Aug. 22, 2005 (JP) 2005-240433

(51) Int. Cl. H01L 33/00

(52) U.S. Cl. 257/100

(57) ABSTRACT

A semiconductor light emitting apparatus comprises: a first lead having a recess; a second lead; embedding resin that embeds therein a portion of the first lead and a portion of the second lead; a semiconductor light emitting device; a wire connecting the semiconductor light emitting device to the second lead; and sealing resin that seals the semiconductor light emitting device and the wire. The semiconductor light emitting device is housed in the recess and has a generally identical shape and size relative to the recess.

### CROSS-REFERENCE TO RELATED APPLICATIONS

This application is based upon and claims the benefit of priority from the prior Japanese Patent Application No. 2004-246114, filed on Aug. 26, 2004, and the Japanese Patent Application No. 2005-240433, filed on Aug. 22, 2005; the entire contents of which are incorporated herein by reference.

### BACKGROUND OF THE INVENTION

1. Field of the Invention

This invention relates to a semiconductor light emitting apparatus such as a light emitting diode (LED), and more particularly to a semiconductor light emitting apparatus that enables high brightness and reliability by improving heat dissipation and relieving stress from resin.

2. Background Art

In recent years, semiconductor light emitting apparatuses have been widely used for various light sources including illumination lamps and displays. In particular, realization of green and blue LEDs has dramatically extended its application to backlights used in liquid crystal displays of mobile phones or other devices. In mobile device applications, a package of the surface mount type called “SMD (Surface Mount Device)” is vital to high density mounting on a circuit board. In order to meet these requirements, various semiconductor light emitting apparatuses of the surface mount type are developed (see, e.g., Japanese Laid-Open Patent Application 2003-8077).

A light emitting apparatus of the surface mount type can be made very thin in its entirety because it is formed from a pair of leads and resin. Such a compact light emitting apparatus of the surface mount type is also suitable to commercial production, and has been used in a wide range of applications.

However, optical output required for a semiconductor light emitting apparatus has been ever increasing. This leads to requirements for large current driving, and hence for further improvement of heat dissipation from the light emitting device. Moreover, applications are increasingly used in severer ambient conditions. Specifically, for example, there is a problem of stress to a light emitting device chip due to expansion and contraction of sealing resin associated with varying ambient temperature. Yielding to this stress, the chip may be stripped off from the lead frame, or subjected to cracks.

### SUMMARY OF THE INVENTION

According to an aspect of the invention, there is provided a semiconductor light emitting apparatus comprising: a first lead having a recess; a second lead; an embedding resin that embeds therein a portion of the first lead and a portion of the second lead; a semiconductor light emitting device housed in the recess and having a generally identical shape and size relative to the recess; a wire connecting the semiconductor light emitting device to the second lead; and a sealing resin that seals the semiconductor light emitting device and the wire.

According to other aspect of the invention, there is provided a semiconductor light emitting apparatus comprising: a first lead; a support provided on the first lead and having a recess; a second lead; an embedding resin that embeds therein a portion of the first lead and a portion of the second lead; a semiconductor light emitting device housed in the recess and having a generally identical shape and size relative to the recess; a wire connecting the semiconductor light emitting device to the second lead; and a sealing resin that seals the semiconductor light emitting device and the wire.

According to other aspect of the invention, there is provided a semiconductor light emitting apparatus comprising: A semiconductor light emitting apparatus comprising: a support made of insulating material and having a recess; a first conductive pattern provided on the surface of the support; a second conductive pattern provided on the surface of the support; a semiconductor light emitting device housed in the recess and having a generally identical shape and size relative to the recess; a wire connecting the semiconductor light emitting device to one of the first and second conductive patterns; and a sealing resin that seals the semiconductor light emitting device and the wire.

### BRIEF DESCRIPTION OF THE DRAWINGS

FIG. 1A is a schematic view illustrating the cross-sectional structure of a semiconductor light emitting apparatus according to an embodiment of the invention;

FIG. 1B is a top view showing the semiconductor light emitting apparatus from which sealing resin 40 thereof is removed;

FIG. 2 is a schematic view showing the cross-sectional structure of a semiconductor light emitting apparatus of a comparative example investigated by the inventors in the course of reaching the invention;

FIG. 3A is a partially enlarged cross section of the first lead 10 of the semiconductor light emitting apparatus of the embodiment of the invention;

FIG. 3B is a schematic cross section of the semiconductor light emitting device 50 bonded to the bottom face of the recess 18;

FIG. 4 is a graphical diagram showing the relation between the thickness of the sealing resin 40 and stress to the semiconductor light emitting device 50;

FIG. 5 is a schematic view illustrating the cross-sectional structure of a semiconductor light emitting device that can be mounted on the semiconductor light emitting apparatus of the embodiment of the invention;

FIG. 6 is a schematic cross section showing a second example of the embodiment of the invention;

FIG. 7 is a schematic cross section showing a third example of the embodiment of the invention;

FIGS. 8A and 8B are schematic views showing a fourth example of the embodiment of the invention;

FIG. 9 is a schematic cross section showing a fifth example of the embodiment of the invention;

FIG. 10 is a schematic cross section showing a sixth example of the embodiment of the invention;

FIG. 11 is a schematic view for illustrating heat dissipation in the semiconductor light emitting apparatus of the fifth example;

FIGS. 12A and 12B are schematic cross sections showing a seventh example of the invention;

FIGS. 13A and 13B are schematic views showing an eighth example of the invention;

FIG. 14 is a schematic perspective view of a semiconductor light emitting apparatus of the eighth example;

FIG. 15 is a schematic cross section of a semiconductor light emitting apparatus of a ninth example;

FIG. 16 is a schematic cross section of a semiconductor light emitting apparatus of a tenth example;

FIG. 17 is a schematic cross section of a semiconductor light emitting apparatus of an eleventh example;

FIG. 18 is a schematic cross section of a semiconductor light emitting apparatus of a twelfth example;

FIG. 19 is a schematic cross section of a semiconductor light emitting apparatus of a thirteenth example; and

FIG. 20 is a schematic cross section of a semiconductor light emitting apparatus of an example of the invention.

### DETAILED DESCRIPTION OF THE INVENTION

Embodiments of the invention will now be described with reference to the drawings.

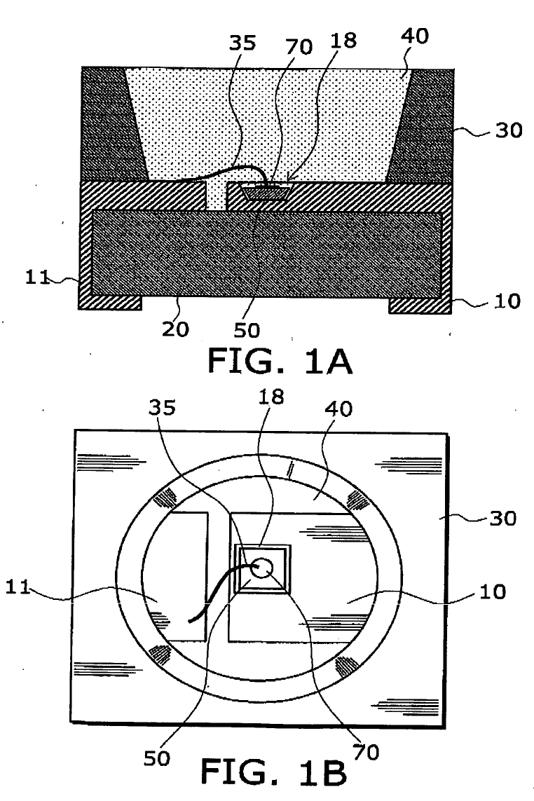

FIG. 1A is a schematic view illustrating the cross-sectional structure of a semiconductor light emitting apparatus according to an embodiment of the invention.

FIG. 1B is a top view showing the semiconductor light emitting apparatus from which sealing resin 40 thereof is removed.

At least a portion of a first lead 10 and a second lead 11 is embedded in high thermal conductive resin 20 (e.g., made of epoxy-based material). The leads 10 and 11 may be connected as a lead frame, for example, during the manufacturing process, and embedded into the high thermal conductive resin 20 either before or after the bonding process for a semiconductor light emitting device 50. The leads 10 and 11 are preferably made of materials such as copper, copper-based alloy, or iron-based alloy.

The lead 10 has a recess 18 formed on the upper face thereof, in which the semiconductor light emitting device 50 is housed. The semiconductor light emitting device 50 has a generally identical shape and size relative to the recess 18. More specifically, in this example, the recess 18 is shaped as a truncated pyramid expanding toward its upper opening. The semiconductor light emitting device 50 also has a generally identical size and is shaped as a truncated pyramid with its sides expanding upward.

A first electrode 70 is formed on the upper face of the semiconductor light emitting device 50 and bonded to the second lead 11 with a wire 35 such as Au (gold) wire. The outer periphery of the high thermal conductive resin 20 embedding the leads 10 and 11 therein is provided with photoreflective resin 30 that is formed with a bevel for reflecting light. By way of example, the photoreflective resin 30 may include polymer resin containing titanium oxide. These are sealed with sealing resin 40 for protecting the semiconductor light emitting device 50 and the bonding wire 35. Examples of transparent sealing resin 40 may include epoxy-based resin and silicone. Phosphors can be dispersed in the sealing resin 40 to convert the wavelength of primary light from the semiconductor light emitting device 50 into secondary light to be extracted with a desired wavelength.

According to this embodiment, the semiconductor light emitting device 50 can be housed in the recess 18 of the lead 10 to alleviate the stress applied from the sealing resin 40 and eliminate the problem of stripping and cracking of the semiconductor light emitting device 50.

In the example shown in FIG. 1B, the wire 35 extends in an oblique direction relative to a direction along which the first and second leads are disposed. That is, the wire 35 extends not right aside (in a direction along which the leads 10 and 11 are disposed and extend) but in an oblique direction from the semiconductor light emitting device 50 toward the lead 11. Thus, a breaking of the wire 35 can be prevented because the length of the wire 35 can be increased. For example, if the body of the sealing resin 20 expands the leads 10 and 11 slant upward and the spacing between the leads 10 and 11 increases. Even in such a case, breaking of the wire 35 can be prevented by extending the wire 35 in an oblique direction as shown in FIG. 1B.

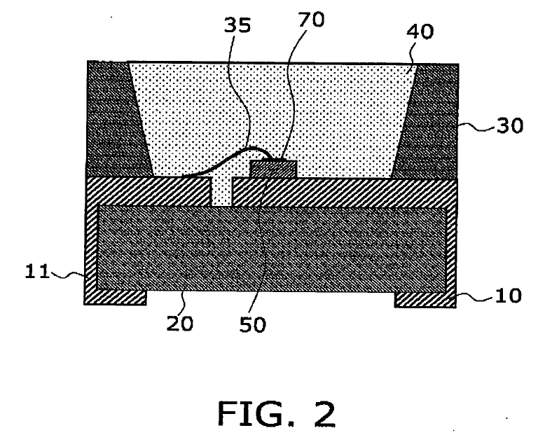

FIG. 2 is a schematic view showing the cross-sectional structure of a semiconductor light emitting apparatus of a comparative example investigated by the inventors in the course of reaching the invention.

This package has a pair of leads 16 and 17. A light emitting device 50 is bonded onto the lead 16 with conductive silver paste (not shown). An electrode 70 provided on the light emitting device 50 is bonded to the other lead 17 by wire bonding 35. The leads 16 and 17 are fixed to highly conductive resin 20. Highly reflective resin 30 is further provided to form a light reflecting plate. The light emitting device 50 is sealed with sealing resin 40 after wire bonding.

However, in this comparative example, the semiconductor light emitting device 50 is mounted on the lead 16 and sealed with the sealing resin 40 around its periphery. Therefore the semiconductor light emitting device 50 is directly subjected to stress associated with expansion and contraction of the resin 40, and may be stripped off or subjected to cracks. In addition, heat dissipation from the semiconductor light emitting device 50 has room for improvement.

In contrast, according to this embodiment, the semiconductor light emitting device 50 can be housed in the recess 18 of the lead 10 to relieve the stress from the sealing resin 40 and also improve heat dissipation. This point will now be described with illustrating more detailed structures.

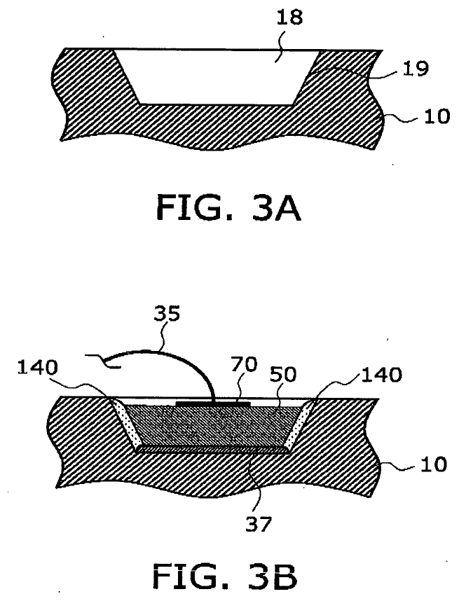

FIG. 3A is a partially enlarged cross section of the first lead 10 of the semiconductor light emitting apparatus of this embodiment.

The lead 10 has a recess 18 pressed or etched in accordance with the shape of the light emitting device 50. The recess 18 may be shaped as a rectangular parallelepiped, a truncated pyramid, or a combination thereof.

FIG. 3B is a schematic cross section of the semiconductor light emitting device 50 bonded to the bottom face of the recess 18.

As shown in this figure, preferably, the sidewall 19 of the recess 18 is close to the side face of the light emitting device 50. To meet the need for bonding the light emitting device 50 by die bonding, the recess 18 preferably has a shape expanding upward or a vertical sidewall. The depth of the recess 18 is preferably about the sum of the thickness of the light emitting device 50 and the thickness of metal eutectic solder or silver paste 37.

The shape of the vertical cross section of the semiconductor light emitting device 50 that is cut along a vertical plane intersecting the surface where the first electrode 70 is provided, is preferably approximated to the shape of the vertical section of the recess 18. That is, the spacing between the semiconductor light emitting device 50 and the sidewall 19 of the recess 18 is preferably small.

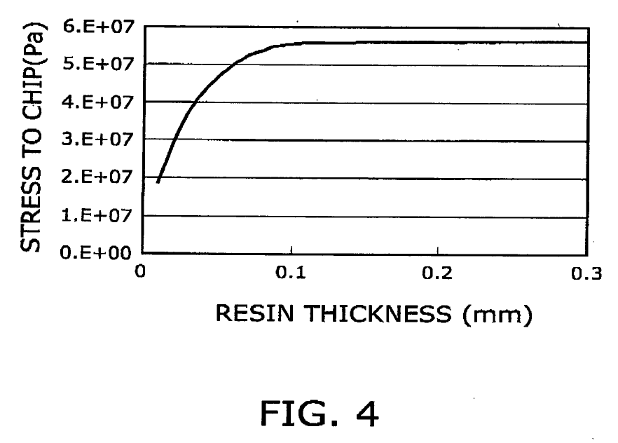

FIG. 4 is a graphical diagram showing the relation between the thickness of the sealing resin 40 and stress to the semiconductor light emitting device 50. More specifically, this figure shows the influence of stress to a chip (semiconductor light emitting device 50) on the thickness of the sealing resin 40 interposed between the semiconductor light emitting device 50 and the sidewall 19 of the recess 18. Table 1 is a list summarizing the relation shown in FIG. 4. In this example, epoxy resin is used for the sealing resin 40.

TABLE 1

| RESIN THICKNESS (mm) | STRESS TO CHIP (Pa) |
|---|---|
| 0.01 | 1.85 × 10⁷ |
| 0.03 | 3.70 × 10⁷ |
| 0.06 | 5.00 × 10⁷ |
| 0.1 | 5.54 × 10⁷ |
| 0.3 | 5.63 × 10⁷ |
| 0.5 | 5.71 × 10⁷ |

It is to be appreciated from FIG. 4 and Table 1 that stress to the chip sharply decreases when the thickness of the sealing resin 40 interposed between the semiconductor light emitting device 50 and the sidewall 19 of the recess 18 falls below 0.1 millimeter. The term “generally identical shape and size” used herein means that the difference of length of the side, difference of height, or gap between the semiconductor light emitting device 50 and the sidewall 19 falls within the range of thickness of sealing resin in which stress to the chip sharply decreases. That is, the thickness of the sealing resin 40 interposed between the semiconductor light emitting device 50 and the sidewall 19 of the recess 18 is preferably 0.1 millimeter or less.

In this case, since the sidewall 19 of the recess is located close to the side face of the semiconductor light emitting device 50, stress due to expansion and contraction of the sealing resin 40 does not directly affect the semiconductor light emitting device 50. As a result, stripping and cracking of the semiconductor light emitting device 50, and hence degradation of its emission characteristics, can be prevented.

In addition, heat generated in the semiconductor light emitting device 50 can be dissipated toward the sidewall 19 of the recess to maintain stable emission characteristics even for large current driving.

Moreover, by configuring the semiconductor light emitting device 50 to have a generally identical size relative to the recess 18, the mounting position of the semiconductor light emitting device 50 can be precisely defined. That is, the position of the recess 18 directly corresponds to the mounting position of the semiconductor light emitting device 50. Therefore, when the semiconductor light emitting device 50 is optically coupled to a lens or optical fiber, no loss due to its mounting position deviation will occur, and advantageously, optical coupling as designed can be always achieved.

Furthermore, according to this embodiment, light emitted laterally or downward from the semiconductor light emitting device 50 can be reflected and extracted upward. For example, in the example shown in FIG. 3B, among the light beams emitted from a light emitting layer (not shown) included in the semiconductor light emitting device 50, the light beams emitted upward can be directly extracted outside. On the other hand, the light beams emitted in lateral or obliquely lateral directions from the light emitting layer of the semiconductor light emitting device 50 can be reflected by the sidewall 19 of the recess 18 and extracted upward. That is, the sidewall 19 of the recess 18 can be used as a reflecting plate to increase the light extraction efficiency. This effect is especially more significant when the substrate material used for the semiconductor light emitting device 50 is transparent to emission wavelength than when it is opaque. For example, when the emission wavelength is visible light, a substrate of the semiconductor light emitting device 50 made of GaAs is opaque to the emission wavelength. However, a substrate made of GaP or GaN is transparent to the emission wavelength. In this case, improvement of light extraction efficiency by reflection at the sidewall 19 can be achieved more significantly.

When a predefined clearance between the semiconductor light emitting device 50 and the sidewall 19 of the recess 18 is required for die bonding the semiconductor device 50 in the recess 18, this can be taken into consideration to determine an optimal spacing.

In addition, as shown in FIG. 3B, the gap between the semiconductor light emitting device 50 and the recess sidewall 19 may be filled with high thermal conductive resin 140. In this case, heat generated in the semiconductor light emitting device 50 can be dissipated through the high thermal conductive resin 140 toward the recess sidewall 19, which enables improvement of temperature characteristics. As a result, for example, thermal resistance, which is about 180° C./W for the structure of the comparative example shown in FIG. 2, can be improved to about 80° C./W.

The bonding wire 35, which is sealed in the sealing resin 40, can have a sufficiently large loop length to absorb stress due to expansion and contraction of resin.

In this way, the rate of lighting failure, which is about 10% resulting from the solder reflow process at 260° C. for a light emitting device of the comparative example shown in FIG. 2, can be reduced to 1% or less.

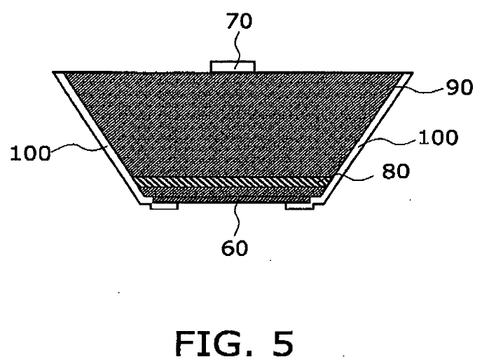

FIG. 5 is a schematic view illustrating the cross-sectional structure of a semiconductor light emitting device that can be mounted on the semiconductor light emitting apparatus of this embodiment.

In this example, the semiconductor light emitting device is shaped generally as a truncated pyramid in accordance with the expanding shape of the recess 18 as illustrated in FIGS. 1A and 1B, and 3A and 3B. The internal structure thereof is described as follows. On one major surface of a transparent substrate 90 is formed a light emitting layer 80, below which is formed a second electrode 60 that also serves as a highly reflective layer. A first electrode 70 is formed on the upper face of the transparent substrate 90. A highly reflective layer 100 including dielectric film is formed on the side face of the transparent substrate 90.

As illustrated in FIG. 3B, the second electrode 60 is die bonded to the lead 10 with solder paste, or AuSn or other eutectic solder 37. The gap between the recess sidewall 19 and the side face of the light emitting device 50 is filled with thin, high thermal conductive resin 140. The first electrode 70 is connected to the second lead 11 via the bonding wire 35. Light emitted from the semiconductor light emitting layer 80 has various components including a component that travels through the transparent substrate 90 and exits out of the light emitting device, a component that is reflected by the side face reflecting layer 100 and exits outside, and a component that is reflected by the lower, second electrode 60 and exits outside. Note that without the reflecting layer 100 on the side face of the light emitting device, a similar effect can be achieved if the sidewall 19 of the recess is highly reflective.

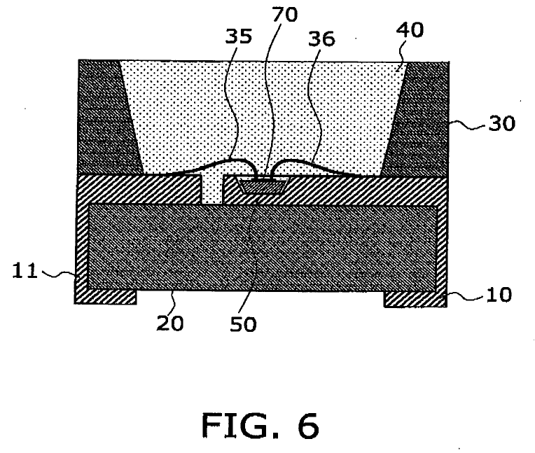

FIG. 6 is a schematic cross section showing a second example of the embodiment of the invention. With regard to this figure, elements similar to those described above with reference to FIGS. 1A to 5 are marked with the same reference numerals and will not be described in detail.

In this example again, the lead 10 has a recess 18 formed on the upper face thereof, in which the semiconductor light emitting device 50 is housed. However, two electrodes (not shown) are provided on the upper face of the semiconductor light emitting device 50. These two electrodes are connected to the leads 11 and 10 via wires 35 and 36, respectively. This is an effective structure when, for example, the semiconductor light emitting device 50 is configured to be formed on an insulating substrate.

In this example again, the semiconductor light emitting device 50 is housed in the recess 18 to avoid much sealing resin 40 from entering the gap between the inner wall surface of the recess 18 and the semiconductor light emitting device 50. As a result, the semiconductor light emitting device 50 can be protected against stress of expansion and contraction of the sealing resin 40. At the same time, heat dissipation from the semiconductor light emitting device 50 to the lead 10 can be facilitated to achieve stable large current driving.

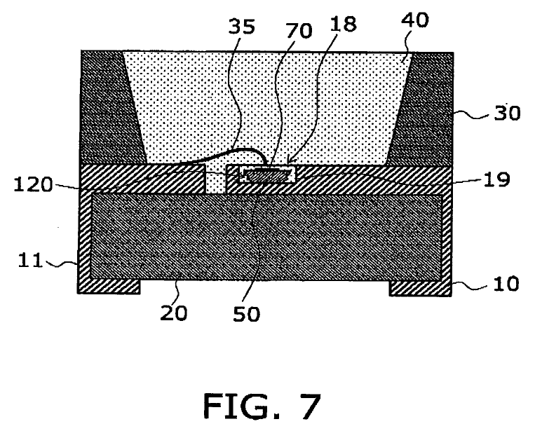

FIG. 7 is a schematic cross section showing a third example of the embodiment of the invention. With regard to this figure, elements similar to those described above with reference to FIGS. 1A to 5 are marked with the same reference numerals and will not be described in detail.

In this example again, the lead 10 has a recess 18, in which the semiconductor light emitting device 50 is housed. The semiconductor light emitting device 50 has a generally identical shape and size relative to the recess 18, but their shapes are not exactly identical. More specifically, asperities 120 are provided on the side face of the semiconductor light emitting device 50 to decrease total reflection of light inside the device, thereby increasing light that can be extracted outside the device. In order to increase the external light extraction efficiency, the reflectance of the recess side face 19 of the lead 10 is preferably increased by silver plating. In this example again, the side face of the semiconductor light emitting device 50 can be placed close to the recess side face 19 to facilitate heat dissipation via the side face 19. As a result, a semiconductor light emitting apparatus having excellent heat dissipation and improved reliability can be achieved.

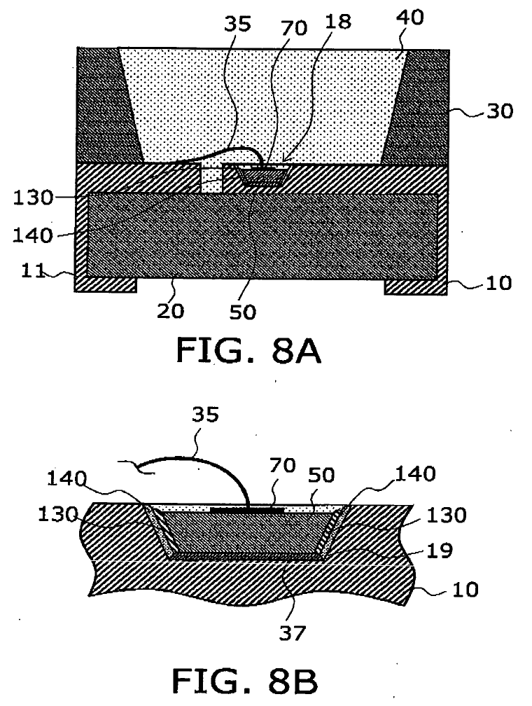

FIGS. 8A and 8B are schematic views showing a fourth example of the embodiment of the invention. More specifically, FIG. 8A is a cross section thereof and FIG. 8B is a partially enlarged cross section thereof.

In this example, the gap between the light emitting device 50 and the recess sidewall 19 is filled with resin having two-layer structure. These resin layers are composed of photoreflective resin 130 and high thermal conductive resin 140 with fillers dispersed therein. The fillers are selected from materials having high photoreflectance such as titanium oxide or potassium titanate in order to increase the reflectance of the surface of the resin serving as matrix. The fillers are mixed into the resin in the form of powder or particles. While FIGS. 8A and 8B show an example in which the photoreflective resin 130 is in contact with the semiconductor light emitting device 50 and the high thermal conductive resin 140 is in contact with the sidewall 19 of the recess, they may be provided vice versa. A multilayer made of three or more layers may also be used. According to this example, light extraction efficiency and heat dissipation can be simultaneously improved.

In addition, a stress relieving effect is also achieved by dispersing fillers.

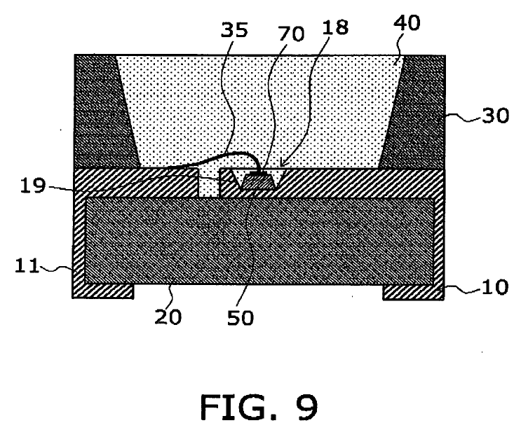

FIG. 9 is a schematic cross section showing a fifth example of the embodiment of the invention.

In this example again, the semiconductor light emitting device 50 is housed in the recess 18, and they have a generally identical shape and size. However, their shapes are not exactly identical. More specifically, in order to prevent the decrease of light extraction efficiency due to reflection from the recess sidewall 19, the recess sidewall 19 is shaped vertically, or beveled so as to expand upward. In this case, more preferably, the sidewall of the recess 18 serves as a reflecting plate. More specifically, the surface of the sidewall 19 can be silver plated, for example, to be highly reflective. As a result, light extraction efficiency can be improved.

On the other hand, the semiconductor light emitting device 50 is shaped as a truncated pyramid slightly expanding downward. Alternatively, the semiconductor light emitting device 50 may be shaped, for example, as a quadrangular prism, or a combination of a quadrangular prism and a truncated pyramid.

In this example, a gap occurs between the sidewall of the recess 18 and the semiconductor light emitting device 50. A large amount of sealing resin 40 interposed in this gap is unfavorable with regard to stress and thermal conduction from the resin 40 as described above with reference to FIG. 2. Taking thermal conduction as an example, the resin 40 typically has a thermal conductivity of 0.2 W/m° C., whereas gold (Au) has a thermal conductivity of 315 W/m° C. In order to ensure thermal conductivity comparable to that of gold, the gap between the sidewall of the recess 18 and the semiconductor light emitting device 50 preferably has an upper limit of about 630 micrometers.

In addition, the gap between the recess sidewall 19 and the light emitting device 50 is preferably filled with a monolayer or laminated structure of high thermal conductive resin and photoreflective resin as described above with reference to FIGS. 8A and 8B.

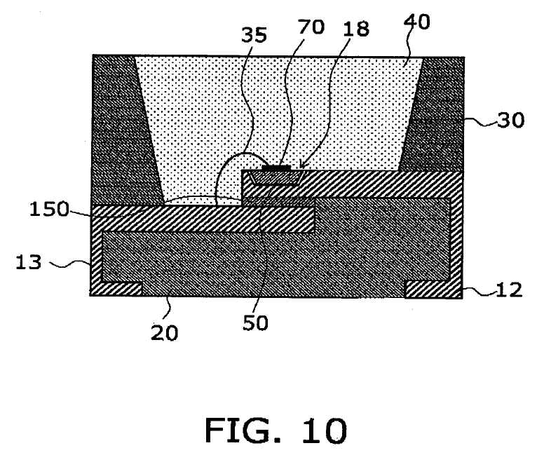

FIG. 10 is a schematic cross section showing a sixth example of the embodiment of the invention.

The structure of the lead recess 18 in which the light emitting device 50 is die bonded is substantially the same as that shown in FIGS. 1A and 1B. The first lead 12 having the recess 18 is stacked with the second lead 13 directly below the recess (particularly where the light emitting device is mounted) via thermal conductive insulating resin 150. The thermal conductive insulating resin 150 may be epoxy-based resin or silicone-based resin.

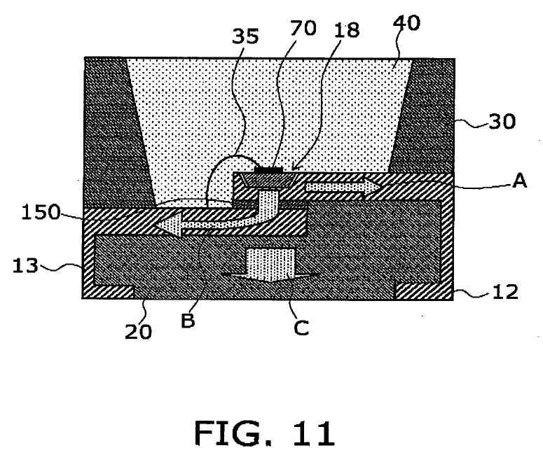

FIG. 11 is a schematic view for illustrating heat dissipation in the semiconductor light emitting apparatus of this example. Heat generated in the semiconductor light emitting device 50 is conducted not only through the first lead 12 as shown by arrow A, but also through the second lead 13 as shown by arrow B, and then dissipated outside. In addition, as shown by arrow C, heat dissipation via the high thermal conductive resin 20 is facilitated. Therefore this structure is suitable to a high power light emitting apparatus having high heat generation due to large current driving.

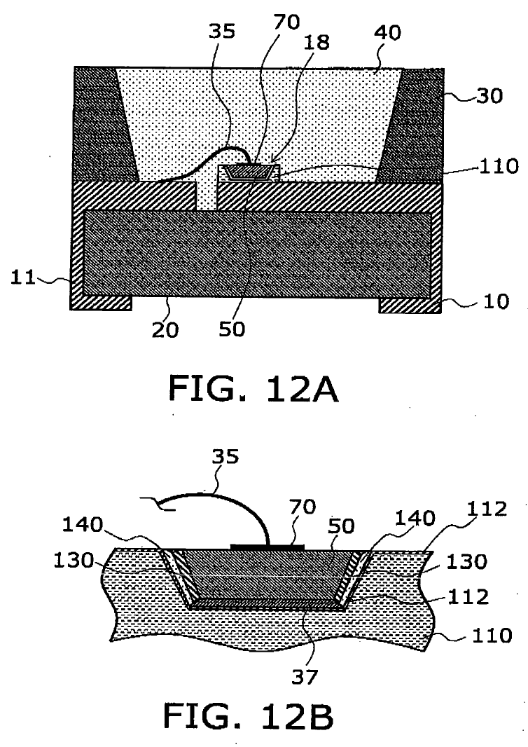

FIGS. 12A and 12B are schematic cross sections showing a seventh example of the invention. More specifically, FIG. 12A is a schematic cross section that generally shows the example, and FIG. 12B is a partially enlarged cross section thereof.

In this example, a submount (or chip carrier) 110 is provided on a lead 14. The light emitting device 50 is die bonded to the bottom face of a recess 18 provided in the submount (or chip carrier) 110, rather than of a recess in the lead. The submount 110, to which the light emitting device 50 is die bonded in advance, can be bonded to the lead 14 with silver paste or eutectic solder 37. In this process, characteristics determination can be made upon installing the light emitting device 50 in the submount 110, and therefore if any failure is found, waste in the subsequent process can be eliminated. The submount 110 may be fabricated from ceramic, diamond, nitride, sapphire, Si, GaP, or SiC.

As shown in FIG. 12B, in order to make electrical connection to the electrode on the die bonding side of the light emitting device 50, the bottom face of the submount recess 18 and the submounting surface to which the lead 14 is bonded, for example, are covered with metallization 112. The metallization 112 is formed by, for example, Mo—Mn thick film sintering, Ni plating, or gold plating. Note that the light emitting device 50 may be die bonded after the submount 110 is bonded to the lead 14. The bonding force between the light emitting device 50 and the submount 110 is stronger than that between the light emitting device 50 and the lead 14. Higher bonding strength is achieved by bonding the submount 110 having a larger contact area to the lead 14 than by bonding the light emitting device 50 directly to the lead. The inner wall surface of the recess of the submount 110 can be smoothed and metallized to achieve high photoreflectance.

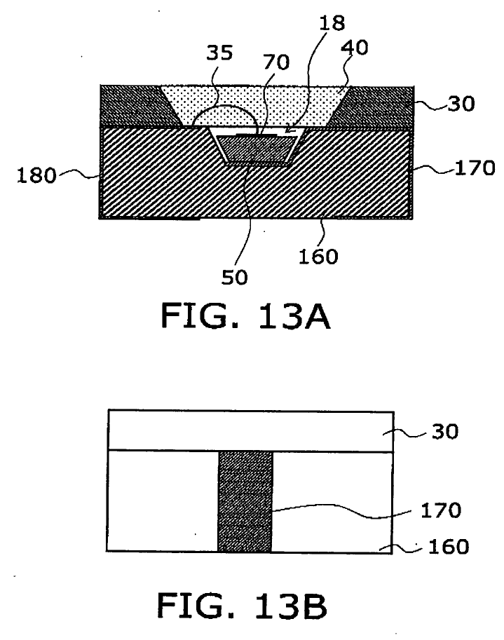

FIGS. 13A and 13B are schematic views showing an eighth example of the invention. More specifically, FIG. 13A is a schematic cross section that generally shows the example, and FIG. 13B is a side view thereof.

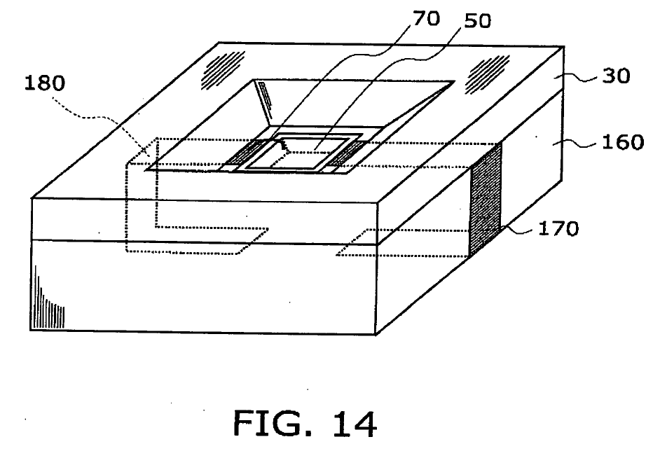

FIG. 14 is a schematic perspective view of a semiconductor light emitting apparatus of this example.

In this example, an insulating substrate 160 is used. The insulating substrate 160 has a recess 18. Metallization 170 extends from the bottom face of the recess 18 to the lower face of the insulating substrate (which is electrically connected to an electrode formed on a packaging board, not shown) via the side face of the insulating substrate 160. The semiconductor light emitting device 50 is bonded to the bottom face of the recess 18 with silver paste, or AuSn or other eutectic solder. The electrode on the upper face of the light emitting device 50 is connected to another metallization 180 via a bonding wire 35. This metallization 180 also extends to the lower face of the insulating substrate 160 for electrical connection to the packaging board, not shown.

Photoreflective resin 30 with a beveled reflecting surface surrounding the recess 18 is provided on the upper face of the insulating substrate 160. Part of the light emitted from the light emitting device 50 is reflected by the photoreflective resin 30, which leads to a higher extraction efficiency. The bonding wire 35 and the light emitting device 50 are sealed with sealing resin 40. The photoreflective resin 30, although not necessarily needed, is effective for enhancing light condensation.

In this example again, advantageously, the side face of the recess 18 can be placed close to the semiconductor light emitting device 50 to relieve stress to the light emitting device 50 due to expansion and contraction of sealing resin. In addition, the smaller the spacing between the side face of the recess 18 and the light emitting device 50, the higher the stress reduction and heat dissipation effect.

Moreover, the effect of filling the gap between the recess 18 and the light emitting device 50 with photoreflective resin and/or high thermal conductive resin is as described above with reference to FIGS. 8A and 8B. The insulating substrate 160 can be made of ceramic, diamond, nitride, sapphire, SiC, GaP, or Si. Among ceramics, AlN, for example, has high thermal conductivity and excellent workability. Therefore an AlN substrate can be used to achieve a compact light emitting apparatus of the surface mount type suitable to large current operation.

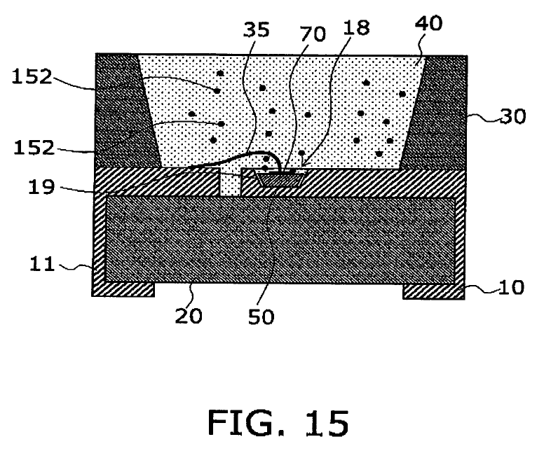

FIG. 15 is a schematic cross section showing a ninth example of the embodiment of the invention. With regard to this figure, elements similar to those described above with reference to FIGS. 1A to 14 are marked with the same reference numerals and will not be described in detail.

In this example again, the semiconductor light emitting device 50 is housed in the recess 18, and they have a generally identical shape and size. The semiconductor device 50, like the first example illustrated in FIGS. 1A and 1B, is shaped as a truncated pyramid expanding upward. Alternatively, the semiconductor light emitting device 50 may be shaped, for example, as a quadrangular prism, or a combination of a quadrangular prism and a truncated pyramid.

In this example, sealing resin 40 mixed with phosphors 152 is provided above and around the semiconductor light emitting device 50. Emitted light from the semiconductor light emitting device 50 is absorbed by the phosphors 152, which is then excited and converts the wavelength to emit light having a longer wavelength. The wavelength associated with the semiconductor light emitting device 50 is preferably in the wavelength band of ultraviolet to blue light. Phosphors absorbing primary light in this wavelength band and emitting secondary light such as red, blue, or yellow light, for example, can be selected. For example, a gallium nitride based semiconductor light emitting device that emits blue light can be selected as the semiconductor light emitting device 50, and phosphors made of silicate can be selected as the phosphors absorbing the blue light and emitting yellow light. In this way, white light can be obtained as a mixture of the blue and yellow light. In this example again, since the semiconductor light emitting device 50 is placed in the recess 18 having a generally identical shape and size, stress to the semiconductor light emitting device 50 can be relieved.

In this example, semiconductor device 50 can be placed in the recess 18 after phosphors are applied or deposited around the semiconductor device 50.

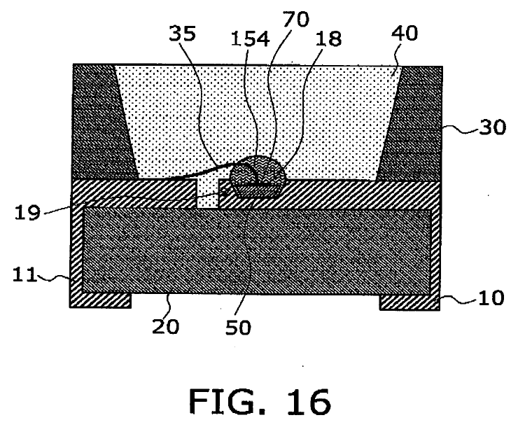

FIG. 16 is a schematic cross section showing a tenth example of the embodiment of the invention. With regard to this figure again, elements similar to those described above with reference to FIGS. 1A to 15 are marked with the same reference numerals and will not be described in detail.

In this example, a region above the recess 18 in which the semiconductor light emitting device 50 is placed is covered with transparent material 154 having a higher refractive index than the sealing resin 40. The transparent material 154 is preferably a resin having a smaller linear expansion coefficient than the sealing resin 40, a resin mixed with fillers to relieve stress, or a low hardness (“soft”) resin such as silicone. Moreover, by shaping the transparent material 154 generally as a hemisphere, the transparent material 154 can be used to serve as a condensing lens. As a result, distribution angle of light emitted outside can be made small, thereby achieving highly convergent directional characteristics.

Furthermore, phosphors can be mixed with the transparent material 154 for wavelength conversion to obtain white light, for example. In this case, silicone is advantageously used as the transparent material 154 because of no degradation for ultraviolet radiation. More specifically, there may be a problem that upon being exposed to ultraviolet radiation, epoxy resin or the like is gradually discolored and its translucency is decreased. In contrast, according to this embodiment, the transparent material 154 is made of silicone with phosphors dispersed therein so that the wavelength of ultraviolet radiation emitted from the semiconductor light emitting device 50 can be converted into visible light. In this way, degradation of the sealing resin 40 can be prevented even when it is made of epoxy resin.

Moreover, fillers can be dispersed in the transparent material 154 to enhance reflectance. As with the other examples, it is understood that stress to the semiconductor light emitting device 50 can be relieved because the semiconductor light emitting device 50 and the recess 18 have a generally identical shape and size.

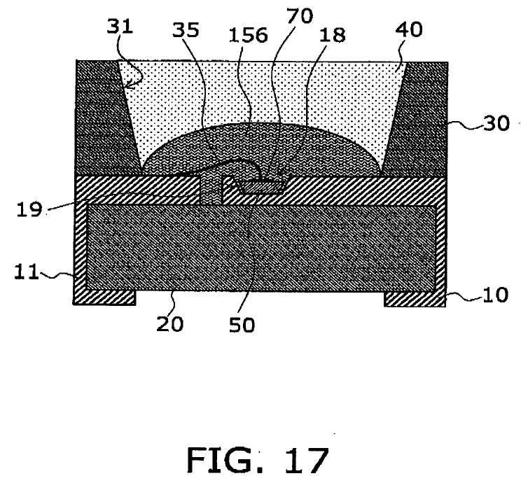

FIG. 17 is a schematic cross section showing an eleventh example of the embodiment of the invention. With regard to this figure again, elements similar to those described above with reference to FIGS. 1A to 16 are marked with the same reference numerals and will not be described in detail.

In this example, a wider area surrounding the region above the recess 18 in which the semiconductor light emitting device 50 is placed is covered with transparent material 156 having a higher refractive index than the sealing resin 40. The transparent material 156 is preferably shaped as a hemisphere, or a structure having a curved surface being convex upward. As with the tenth example, phosphors can be mixed in the transparent material 156 to obtain white light and degradation of the sealing resin 40 due to ultraviolet radiation can be prevented. Moreover, fillers can be dispersed in the transparent material 156 to scatter light and obtain uniform white light.

Moreover, in this example again, the transparent material 156 can be used to serve as a condensing lens, and the reflecting surface 31 of the photoreflective resin 30 can be utilized. As a result, the light distribution angle can be easily controlled, and the directivity becomes more controllable. As with the other examples, it is understood that stress to the semiconductor device 50 can be relieved because the semiconductor light emitting device 50 and the recess 18 have a generally identical shape and size.

Embodiments of the invention have been described with reference to examples. However, the invention is not limited to these examples.

For example, the invention is not limited to the use of InGaAlP-based and GaN-based semiconductor light emitting device chips. GaAlAs-based, InP-based, and various other group III-V compound semiconductors, or group II-VI compound semiconductors or various other semiconductors may be used.

Any shape, size, material, and arrangement of various elements including the semiconductor light emitting device chip, leads, embedding resin, and sealing resin composing the semiconductor light emitting apparatus that are adapted by those skilled in the art are also encompassed within the scope of the invention as long as they include the features of the invention.

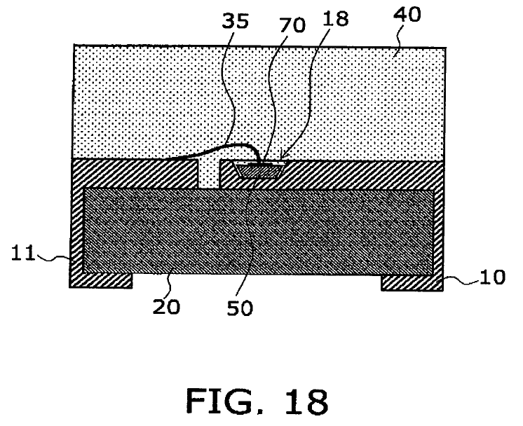

For example, in the example shown in FIG. 18, without photoreflective resin 30 as illustrated in FIGS. 1A and 1B, the upper face of the leads 10 and 11 is covered with sealing resin 40. In this case, light can be emitted in all directions from the upper face, achieving wide-angle light distribution characteristics.

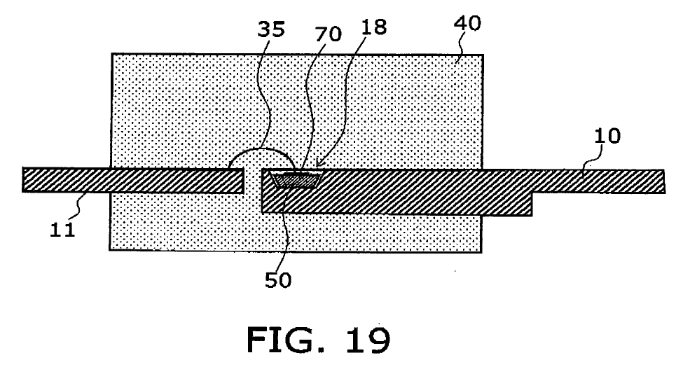

In the example shown in FIG. 19, each of the leads 10 and 11 are formed straight and the opposed portions are sealed with sealing resin 40. The structure like this can also be used.

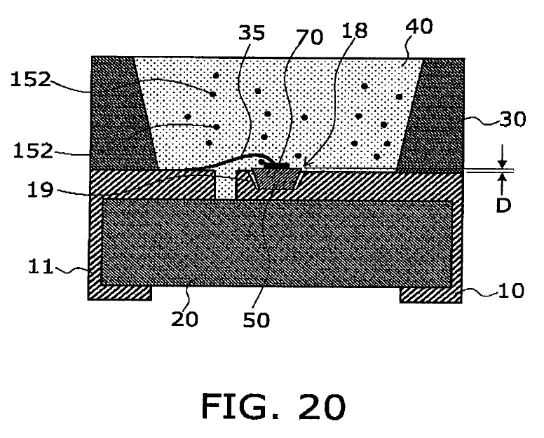

FIG. 20 is a schematic cross section for supplemental remarks common to the foregoing examples.

The term “to house” used herein also covers the situation in which the upper face of the semiconductor light emitting device 50 protrudes upward from the opening edge of the recess 18 provided in the first lead. As long as the semiconductor light emitting device 50 is directly affected by the stress due to expansion and contraction of the sealing resin 40, the semiconductor light emitting device 50 may protrude a vertical distance D from the opening edge of the recess 18. In this case again, the relation on the stress generated between the semiconductor light emitting device 50 and the sealing resin 40 illustrated in FIG. 4 is applicable. Therefore the vertical distance D is preferably not larger than 0.1 millimeter.

Possible combinations of two or more of the examples described above with reference to FIGS. 1A to 20 are also encompassed within the scope of the invention.

1. A semiconductor light emitting apparatus comprising:
a first lead having a recess;
a second lead;
an embedding resin that embeds therein a portion of the first lead and a portion of the second lead;
a semiconductor light emitting device housed in the recess and having a generally identical shape and size relative to the recess;
a wire connecting the semiconductor light emitting device to the second lead; and
a sealing resin that seals the semiconductor light emitting device and the wire.

2. A semiconductor light emitting apparatus according to claim 1, wherein the sealing resin does not substantially interpose in a gap between an inner wall of the recess and the semiconductor light emitting device.

3. A semiconductor light emitting apparatus according to claim 1, wherein a reflecting film is provided between an inner wall of the recess and the semiconductor light emitting device.

4. A semiconductor light emitting apparatus according to claim 1, wherein a layer is provided between an inner wall of the recess and the semiconductor light emitting device, and a material having a higher thermal conductivity than the sealing resin is provided in the layer.

5. A semiconductor light emitting apparatus according to claim 1, further comprising reflecting resin surrounding the recess and having a bevel that reflects light emitted from the semiconductor light emitting device.

6. A semiconductor light emitting apparatus according to claim 5, wherein
the embedding resin and the reflecting resin are made of mutually different materials, and
the embedding resin has a higher thermal conductivity than the reflecting resin.

7. A semiconductor light emitting apparatus according to claim 1, wherein
phosphors are provided on the upper face of the semiconductor device to convert a wavelength of the emitted light from the semiconductor light emitting device.

8. A semiconductor light emitting apparatus according to claim 1, wherein a portion of transparent material having a curved surface that is convex upward and having a higher refractive index than the sealing resin is provided between the recess and the semiconductor device, and the sealing resin.

9. A semiconductor light emitting apparatus according to claim 8, wherein the hardness of the transparent material is lower than the hardness of the sealing resin.

10. A semiconductor light emitting apparatus according to claim 1, wherein the wire extends in an oblique direction relative to a direction along which the first and second leads are disposed.

11. A semiconductor light emitting apparatus comprising:
a first lead;
a support provided on the first lead and having a recess;
a second lead;
an embedding resin that embeds therein a portion of the first lead and a portion of the second lead;
a semiconductor light emitting device housed in the recess and having a generally identical shape and size relative to the recess;
a wire connecting the semiconductor light emitting device to the second lead; and
a sealing resin that seals the semiconductor light emitting device and the wire.

12. A semiconductor light emitting apparatus according to claim 11, wherein the sealing resin does not substantially interpose in a gap between an inner wall of the recess and the semiconductor light emitting device.

13. A semiconductor light emitting apparatus according to claim 11, wherein a reflecting film is provided between an inner wall of the recess and the semiconductor light emitting device.

14. A semiconductor light emitting apparatus according to claim 11, wherein a layer is provided between an inner wall of the recess and the semiconductor light emitting device, and a material having a higher thermal conductivity than the sealing resin is provided in the layer.

15. A semiconductor light emitting apparatus according to claim 11, further comprising a reflecting resin surrounding the recess and having a bevel that reflects light emitted from the semiconductor light emitting device.

16. A semiconductor light emitting apparatus comprising:
a support made of insulating material and having a recess;
a first conductive pattern provided on the surface of the support;
a second conductive pattern provided on the surface of the support;
a semiconductor light emitting device housed in the recess and having a generally identical shape and size relative to the recess;
a wire connecting the semiconductor light emitting device
to one of the first and second conductive patterns; and
a sealing resin that seals the semiconductor light emitting device and the wire.

17. A semiconductor light emitting apparatus according to claim 16, wherein the sealing resin does not substantially interpose in a gap between an inner wall of the recess and the semiconductor light emitting device.

18. A semiconductor light emitting apparatus according to claim 16, wherein a reflecting film is provided between an inner wall of the recess and the semiconductor light emitting device.

19. A semiconductor light emitting apparatus according to claim 16, wherein a layer is provided between an inner wall of the recess and the semiconductor light emitting device, and a material having a higher thermal conductivity than the sealing resin is provided in the layer.

20. A semiconductor light emitting apparatus according to claim 16, further comprising reflecting resin surrounding the recess and having a bevel that reflects light emitted from the semiconductor light emitting device.
